(19) United States
(12) Patent Application Publication
(10) Pub. No.: US 2026/0267088 A1
(43) Pub. Date: Sep. 10, 2026

(54) COUPLING DEVICE FOR COUPLING AT LEAST ONE LASER BEAM INTO AT LEAST ONE FIBER ARRAY

(71) Applicant: FIBERBRIDGE PHOTONICS GMBH, Hannover (DE)

(72) Inventors: Thomas THEEG, Seelze (DE); Thomas BINHAMMER, Seelze (DE); Philipp GERSEMA, Hannover (DE)

(73) Assignee: FIBERBRIDGE PHOTONICS GMBH, Hannover (DE)

(21) Appl. No.: 19/530,903

(22) Filed: Feb. 5, 2026

(30) Foreign Application Priority Data
Mar. 4, 2025 (DE) 102025108144.1

(51) Int. Cl. G02B 6/42; G02F 1/33

(52) U.S. Cl. CPC G02B 6/4214; G02B 6/4206; G02F 1/33

(57) ABSTRACT

The present invention relates to a coupling device for coupling at least one laser beam (A) into at least one fiber array, comprising at least one first deflection element or at least one first beam splitter which is designed and arranged to receive and deflect or split the laser beam (A) multiple times, at least one focusing element which is designed and arranged to receive and focus the deflected or split laser beams (A), and at least the fiber array which has a plurality of fiber elements arranged at least one-dimensionally, preferably two-dimensionally, relative to each other.

### CROSS-REFERENCE TO RELATED APPLICATION

This application claims priority to German Patent Application Serial No. 102025108144.1 filed March 4, 2025, which is incorporated herein by reference.

### FIELD OF THE INVENTION

The present invention relates to a coupling device for coupling at least one laser beam into at least one fiber array.

### BACKGROUND

Nowadays, glass fibers are used in many different technical fields. The technical and particularly high-technical applications include the use of glass fibers for light transmission. Thus, glass fibers are used for data transmission by means of light; in this case, the glass fibers can also be referred to as optical waveguides or passive glass fibers. Glass fibers are also used in medicine for example for illumination and for producing images, for example in microscopes, in inspection cameras and in endoscopes. Furthermore, glass fibers are used in sensors which can then be referred to as fiber-optic sensors.

A further field of application for glass fibers is laser technology. Here, the laser radiation can be guided as signal light radiation by means of a passive glass fiber from a laser radiation source as a signal light source or as a signal light radiation source to a processing point in order to carry out there, for example in material processing or in medicine, for example, cutting or welding. The laser beam can also be fed to a sample as laser radiation in this way, for example in measurement technology, microscopy or spectroscopy. The use of passive glass fibers for guiding a laser beam can take place, for example, in applications such as mechanical engineering, telecommunications, medical technology and sensor technology.

Glass fibers typically have a fiber core, which consists of pure glass such as pure quartz glass, and is often doped with germanium in the case of passive glass fibers; in the case active glass fibers, neodymium, ytterbium, erbium, thulium and holmium are commonly used as doping elements. In certain cases, the fiber cladding can also be doped; this applies to both passive and active glass fibers. Depending on the size and the numerical aperture of the fiber core, it is possible to distinguish between single-mode and multi-mode glass fibers. In addition, the fiber core can still have polarization-maintaining properties for the light and can therefore be referred to as polarization-maintaining glass fibers (PM). They can also be photonic crystal glass fibers and hollow-core glass fibers. Even if the main field of application relates to glass fibers, polymer fibers or fibers made of other materials, for example so-called soft glass fibers for the mid IR range, can likewise be used for such applications.

The fiber core is usually surrounded radially from the outside by at least one fiber cladding, which is usually closed in the circumferential direction and thus completely surrounds the fiber core, apart from the two open ends of the glass fiber. The fiber cladding is also usually made of quartz glass.

Usually, both passive glass fibers and active glass fibers are surrounded by a fiber coating made of polymer, for example, comparable to the fiber cladding, which can then be attributed to the glass fiber. The fiber coating can serve to mechanically protect the glass interior of the glass fiber and influence the optical properties thereof. In the case of glass fibers in which the light is guided exclusively in the fiber core (single-clad glass fibers), the fiber coating is usually primarily used for mechanical protection. Glass fibers which guide light in the fiber core and in the fiber cladding (double-clad glass fibers) are usually designed with a fiber coating for fulfilling mechanical and optical properties.

Two cross-sectional shapes that occur frequently in practice for the fiber cladding are cylindrical and octagonal. The octagonal shape for the fiber cladding is used in particular in the case of active glass fibers.

Such glass fibers can be produced in large lengths and are usually available as roll products. The diameter of the fiber cladding usually varies between approximately 80 µm and approximately 1 mm. The larger fiber diameters in particular are often referred to in practice as rod-type fibers.

Signal light or signal light radiation can thus be supplied via a glass fiber, which is therefore referred to as a beam guidance device and which can be implemented as a cable or beam feed cable. Beam feed cables for guiding the signal light radiation from the laser system to the application or to the location of the application are now commonly implemented with exactly one glass fiber per beam feed cable.

As already mentioned, the fiber optic cable offers the great advantage that the light from the signal light radiation can be guided flexibly over long distances within the fiber optic cable, e.g., on a robot arm, and reliably to the application location. At the application point, the individual glass fiber typically emits a round laser beam from a single-mode or multi-mode glass fiber.

However, the trend on the market shows that a modified laser beam, i.e., with a special beam profile that is not perfectly round, is desired for many applications such as welding, additive manufacturing and surface treatment, as well as for the cleaning of materials. This can result in significant benefits for the given application, and better or new technical solutions can thus be implemented or lower unit costs achieved.

There are already various beam shaping approaches for modifying or shaping the individual round laser beam from the beam feed cable for the application. This brings great advantages for some applications.

However, for technical reasons, many interesting or necessary laser beam configurations cannot as yet be achieved. In addition, power transport via a single glass fiber reaches its limits for physical and technical reasons. Furthermore, for many applications it is desirable to increase the available optical power for the corresponding application at the application location, for example in order to be able to weld better or to implement additive manufacturing processes more quickly (e.g., selective laser melting).

In any case, it is useful or necessary for many applications to guide, direct or transmit the signal light radiation over a certain distance, in particular from the location where the signal light radiation is generated or amplified, in order to use, amplify or modify the signal light radiation there. The spectrum of signal light radiation can have a width from a few kHz to several hundred THz.

DE 10 2023 133 492.1 (not published) describes a beam guidance device for guiding signal light radiation, having at least one fiber input element which is designed to receive the signal light radiation, having at least one fiber output element which is designed to emit the signal light radiation, and having a plurality of fiber elements which are fixedly connected at one end to the fiber input element and at the opposite end to the fiber output element and are designed to guide the signal light radiation from the fiber input element to the fiber output element.

In this way, a plurality of fiber elements can be fixedly connected to each other both at their entry sides by means of the common fiber input element and at their exit sides by means of the common fiber output element, in order to guide individual signal light radiation, laser radiation or laser beams parallel to each other. In this way, a beam guidance device can be created, in order to guide a plurality of signal light radiation through the fiber elements parallel to one another from the fiber input element to the fiber output element, so that the signal light radiation can be generated and/or amplified on the side of the fiber input element, and applied or used together on the side of the fiber output element.

The reception of the signal light radiation, laser radiation or the laser beams via the fiber input element can be realized via a free-beam coupling into the fiber elements or via a material connection (e.g., fiber splice connection) with the fiber elements. It is also possible to couple the signal light radiation(s) into the fiber elements at the fiber input element by means of a beam guidance and deflection unit. This can be done using a galvo scanner, an acousto-optic deflector (also called an acousto-optic modulator), or another beam deflection system.

### SUMMARY

One object of the present invention is to improve and/or expand the possibilities of coupling laser beams into a plurality of fiber elements. The coupling should in particular be possible for laser beams with comparatively high powers, such as those exceeding 100 W. Additionally or alternatively, the coupling into the fiber elements should be able to take place simultaneously or sequentially. This should be possible in particular for a laser beam of a laser source or for a plurality of laser beams from a plurality of laser sources. This should in particular be implementable and/or be usable in a way that is as flexible as possible. In any case, this should in particular be possible for laser beams for industrial applications in the processing of workpieces, such as laser welding. At least one alternative to the known possibilities is intended to be created.

The object is achieved according to the invention by a coupling device having the features of claim 1. Advantageous developments are described in the dependent claims.

The present invention thus relates to a coupling device for coupling at least one laser beam into at least one fiber array comprising at least one first deflection element or at least one first beam splitter, which is designed and arranged to receive and deflect or split the laser beam multiple times, at least one focusing element which is designed and arranged to receive and focus the deflected or split laser beams, and at least the fiber array which has a plurality of fiber elements arranged at least one-dimensionally, preferably two-dimensionally, relative to each other.

The laser beam can consist of continuous or pulsed radiation with any optical central wavelength. The laser beam may also be referred to as laser radiation.

A deflection element is understood to be any possibility of receiving an incoming single laser beam on one side and emitting it again on the other, preferably opposite, side by means of the deflection element, with optical power that is as unchanged as possible, but as at least two laser beams. The outgoing laser beams can extend in at least two different directions or in two identical directions, i.e., parallel to each other. These two directions can be able to be adjusted or influenced by a control system. This can be achieved in particular by means of a non-mechanical deflection element. This can preferably be implemented using an acousto-optic modulator (AOM), which can completely deflect the incoming laser beam in alternative directions.

Thus, at least two outgoing laser beams can be generated, each having at least substantially the same optical power as the incoming laser beam, and output or emitted in different directions, so that the two outgoing laser beams can be described as multiple laser beams that can exist with a temporal offset or alternatively to each other. In particular, the deflection element can switch back and forth between these two outgoing or resulting laser beams.

In any case, according to the invention, a single laser beam can be received by the first deflection element in this way and alternatively directed in at least two directions as alternative laser beams to the focusing element, so that the two outgoing laser beams can each be focused there and then, i.e., in focused form, each coupled into a fiber element, of the fiber array. There, the two laser beams can extend or be guided, and reach an application at the end of the fiber array, on which the two laser beams can act one after the other or alternatively to each other.

Alternatively, such a deflection element can also act like a beam splitter, which will be described in more detail below, and split the incoming laser beam into at least two simultaneously existing outgoing laser beams. This can be described as temporally static, whereas the generation of temporally offset laser beams can be described as temporally dynamic.

In this case, a beam splitter is understood to be any possibility of receiving an incoming single laser beam on one side and splitting it into at least two outgoing laser beams by means of the beam splitter, which beams exit the beam splitter again simultaneously, in one direction each, preferably parallel to each other. In this case, the optical power of the incoming laser beam is thus split between the two emerging or outgoing laser beams, so that the sum of the optical powers of the two outgoing laser beams corresponds at least substantially to the optical power of the incoming laser beam. This can preferably be implemented using a diffractive optical element (DOE), a grating, an LCD display, or a temporally static acousto-optic modulator (AOM) that can simultaneously generate at least two emerging laser beams.

In any case, according to the invention, in this way a single laser beam can alternatively be received by the first beam splitter and simultaneously transferred in at least two directions as simultaneous laser beams to the focusing element, so that the two outgoing laser beams can each be focused there and then, i.e., in focused form, each be coupled into a fiber element of the fiber array. There, the two laser beams can be transferred or guided and reach an application at the end of the fiber array, on which the two laser beams can act simultaneously or together.

In this case, the fiber elements or optical fibers of the fiber array can be arranged one-dimensionally or two-dimensionally relative to each other, at least where the laser beams can enter or be coupled in, which can increase the design freedom of the arrangement of the fiber elements, at least at the point of entry or coupling in, and thus also the design freedom of the arrangement of the other elements of the coupling device according to the invention. The one-dimensional arrangement of the fiber elements can also be described as linear or rectilinear. Alternatively, a two-dimensional arrangement of fiber elements can have a plurality of fiber elements which can be arranged next to each other in two spatial directions, such as a two-dimensional matrix, or an arrangement of fiber elements which are arranged one behind the other, but in a two-dimensional geometry such as an arc, a circle, an oval, a rectangle or square, a hexagon or the like.

In any case, the fiber elements can be transferred unvaryingly along the fiber array, or the arrangement of the fiber elements can change in portions or completely along the length of the fiber array. In particular, the arrangement of the fiber elements of the fiber array at the point of exit of the laser radiation can be the same as or different from that upon entry, which can also increase the design freedom, in particular for the use of the exiting laser radiation.

In accordance with the fiber array, the first deflection element or the first beam splitter can be designed to generate a one-dimensional or two-dimensional arrangement of emerging laser radiation, which can each be coupled through the focusing element into the corresponding fiber elements of the fiber array.

In any case, any type of optics can be used as a focusing element, which can bring about optical focusing of at least two laser beams towards the fiber array. For this purpose, a one-piece, i.e., integrally designed, focusing element, such as a single lens, can be used. It is also possible to use a plurality of individual elements, each of which focuses a laser beam and thus work together functionally, so as to be referred to collectively as a focusing element.

In any case, yet further optical elements can be arranged between the first deflection element or the first beam splitter, the focusing element and the fiber array or its entry side, along the propagation direction of the laser beams, as will be described in more detail below.

In any case, the first deflection element can generate more than two laser beams that emerge with a temporal offset or simultaneously. The beam splitter can also generate more than two laser beams that emerge simultaneously. This can further increase the design freedom of the coupling device according to the invention.

In particular, the properties of the first deflection element and/or of the first beam splitter can be combined in at least two steps or in at least two planes, arranged functionally or spatially one after the other along the propagation direction of the laser beams, in order to further increase the design freedom of the coupling device according to the invention. In this case, only deflection elements or beam splitters can be used in both or all planes. Alternatively, deflection elements and beam splitters can also be combined in both or all planes. Preferred combination options will be described in more detail below. This can also take place for more than two planes in succession. In this case, identical or different deflection elements and/or beam splitters can always be used or combined.

The deflection element or the beam splitter can emit the partial beams in different and non-parallel directions, as mentioned previously. For the coupling and for the arrangement of the fiber elements, this direction can be compensated for or taken into account in each case, for each partial beam. Preferably, the coupling arrangement can therefore include an angle-correcting element which can align the individual partial beams parallel to each other. This can be achieved, as will be explained in more detail below, through a suitable geometry, a distance of the focusing element, or an arrangement of wedges, or freeform optics.

The beam parameters of the laser beam can preferably be designed in the coupling device such that the beam radii at the deflection or beam splitting elements are large enough to prevent thermal problems and destruction of the components, and at the same time are appropriately positioned in front of each fiber element and strike a small beam radius corresponding to the fiber, which can allow efficient and non-destructive coupling.

In particular, the one- or multi-dimensional arrangement of the inlet and/or outlet fibers of the fiber array can be important, it being possible for the geometry of the arrangement of the fiber elements on the inlet and outlet sides to differ. A plurality of fiber elements in a fixed geometric arrangement, which can emit laser radiation either simultaneously (i.e., temporally statically) or in a temporally offset manner (i.e., temporally dynamically), can open up numerous new technologies and/or methods. In this case, the laser radiation from the respective channels can be either coherent or incoherent to each other. In any case, the generation of parallel laser beams directed towards a common application point can be referred to as multi-beam.

In material processing, multi-beam arrangements can allow scaling of laser power or parallelization of processing processes, and thereby increased speed and productivity. Targeted pattern generation or beam shaping can allow new process techniques, e.g., in surface structuring. The coherent or incoherent superposition of a plurality of high-power lasers by means of such a fiber array can allow scaling of the laser power into the range above 10 kW. This can form the basis for many applications in the defense or space travel industry, such as satellite communication. Fast-switching or dynamically modifiable laser beams from fiber arrays can also be used in the field of quantum computing or in communication. In this case, in technological terms it is already possible to arrange more than a hundred channels in such fiber arrays with high precision. This highlights the need for new technological approaches to the temporally dynamic or temporally static coupling of one or more laser sources into a plurality of glass fibers, in particular coupling into single-mode or LMA fibers.

While technologies for beam deflection and beam splitting per se are largely known as prior art, the combination of beam deflection or beam splitting and coupling of the laser beam, split into individual laser beams, into a fiber array is not yet known. The combination of beam splitting, whether by simultaneous splitting or by temporally offset deflection, of an incoming laser beam into a plurality of channels or into individual laser beams, and their coupling into a common fiber array, e.g., in the form of a glass fiber, in particular a single-mode or large-mode area (LMA) glass fiber, can make it possible to ensure the corresponding beam diameters and angles for the respective deflection element or for the respective beam splitter, and an efficient and damage-free coupling into each individual fiber element of the fiber array, which in this form goes beyond the prior art. In particular, for high-power lasers with more than 100 W of power, damage thresholds, thermal effects and scattered radiation can be taken into account in this way. According to the invention, large beam radii can be allowed for the deflection element or for the beam splitter for high efficiency and minimization of thermal effects, and the splitting or deflection can be carried out at a very small angle, in particular with a few mrad in the case of an acousto-optic modulator (AOM) or diffractive optical element (DOE).

In order, in this case, to achieve a complete separation of the individual modes of the individual laser beams, generated by deflection or beam splitting, as sub-beams, long path distances may be required, which, however, may in practice often be disadvantageous due to lack of compactness and low stability. Therefore, simple scaling of the distances can be advantageous, as will be described in more detail below. The angular divergence of the partial beams can be compensated for, and each individual beam can be focused to the appropriate position of the respective glass fiber of the fiber array, in such a way that optimal coupling efficiency can be achieved. Uncoupled light, whether between the fiber elements or light guided in a cladding mode, can preferably be controlled and removed, as it can lead to undesirable thermal effects or destruction, in particular in the high power range.

According to one aspect of the invention, the coupling device comprises at least the first deflection element, which is designed and arranged to receive the laser beam and deflect it multiple times, and furthermore at least one first beam splitter, which is designed and arranged to receive one of the deflected laser beams and split it to the focusing element.

This can represent a concrete way to deflect and/or split the incoming laser beam twice in succession, as previously described. In this case, the properties of a deflection element in the first plane and of a beam splitter in the second plane, i.e., in that order, can be combined. In this case, both the deflection element and the beam splitter can be designed to be one-dimensionally or two-dimensionally deflecting or beam-splitting. In particular, both the deflection element and the beam splitter can be designed and arranged to be one-dimensionally deflecting or beam-splitting, in order to create a two-dimensional arrangement of laser beams and couple them through the focusing element into the corresponding fiber elements of the fiber array.

According to a further aspect of the invention, the coupling device further comprises at least two first beam splitters, which are designed and arranged to each receive one of the deflected laser beams and split it to the focusing element.

This can represent an alternative, concrete way to deflect and/or split the incoming laser beam twice in succession, as previously described. In this case, the properties of a deflection element in the first plane and a plurality of beam splitters, arranged or acting in parallel, in the second plane, i.e., in this order, can be combined as previously described, but now by means of a plurality of beam splitters. Preferably, in this case, only beam splitters can be used in the second plane, in order to utilize the properties of beam splitters uniformly per plane.

According to a further aspect of the invention, the coupling device further comprises at least one second deflection element which is designed and arranged to receive the other of the deflected laser beams and to deflect them multiple times towards the focusing element.

This can represent an alternative, concrete way to deflect and/or split the incoming laser beam twice in succession, as previously described. In this case, the properties of a deflection element in the first plane, as well as, functionally parallel with one another, those of at least one first beam splitter and at least one second deflection element in the second plane, i.e., in that order, can be combined as previously described. Accordingly, the properties of beam splitters and deflection elements can be combined in the second plane.

According to a further aspect of the invention, the coupling device comprises at least the first beam splitter, which is designed and arranged to receive and split the laser beam, and furthermore at least one first deflection element, which is designed and arranged to receive one of the split laser beams and to deflect it multiple times towards the focusing element.

This can represent an alternative, concrete way to deflect and/or split the incoming laser beam twice in succession, as previously described. In this case, the beam is first split using the first beam splitter in the first plane, and then one of the laser beams is deflected using the first deflection element in the second plane. This can increase the number of possible designs.

According to a further aspect of the invention, the coupling device further comprises at least two first deflection elements, which are designed and arranged to each receive one of the split laser beams and deflect it multiple times to the focusing element.

This can represent an alternative, concrete way to deflect and/or split the incoming laser beam twice in succession, as previously described. In this case, at least two laser beams are deflected again in parallel or simultaneously in the second plane, each by means of a first deflection element. Preferably, only first deflection elements are used in the second plane, in order to utilize the properties of deflection elements uniformly per plane. This can increase the number of possible designs.

According to a further aspect of the invention, the coupling device further comprises at least one second beam splitter, which is designed and arranged to receive the other of the split laser beams and to split them to the focusing element.

This can represent an alternative, concrete way to deflect and/or split the incoming laser beam twice in succession, as previously described. In this case, too, the properties of beam splitters and deflection elements can be combined in two planes in succession.

According to a further aspect of the invention, the coupling device comprises the first deflection element, which is designed and arranged to receive the laser beam and deflect it multiple times, and furthermore at least two second deflection elements, which are designed and arranged to each receive one of the deflected laser beams from the first deflection element and deflect it multiple times to the focusing element.

This can represent an alternative concrete way of deflecting the incoming laser beam twice in succession, as previously described, in this case preferably an exclusive use of deflection elements in both planes being possible.

According to a further aspect of the invention, the coupling device comprises the first beam splitter, which is designed and arranged to receive and split the laser beam, and furthermore at least two second beam splitters, which are designed and arranged to each receive one of the split laser beams from the first beam splitter and split it to the focusing element.

This can represent an alternative concrete way of splitting the incoming laser beam twice in succession, as previously described, in this case preferably an exclusive use of beam splitters in both planes being possible.

According to another aspect of the invention, the first deflection element is a first acousto-optic modulator (AOM), preferably and a second deflection element is a second acousto-optic modulator.

This can represent a concrete way of implementation in order to utilize the corresponding properties and advantages.

According to a further aspect of the invention, the first deflection element, preferably and a second deflection element, is designed to deflect the laser beam one dimensionally or two dimensionally.

This can constitute a concrete possibility for implementation, as described above.

According to another aspect of the invention, the first beam splitter is a first diffractive optical element, preferably and a second beam splitter is a second diffractive optical element.

This can represent a concrete way of implementation in order to utilize the corresponding properties and advantages.

According to a further aspect of the invention, the first beam splitter, preferably and a second beam splitter, is designed to split the laser beam one-dimensionally or two-dimensionally.

This can constitute a concrete possibility for implementation, as described above.

According to another aspect of the invention, the focusing element is a lens, a micro-lens array, a concave mirror, a paraboloid or freeform optics.

This can represent various concrete ways of implementation, in order to utilize the corresponding properties and advantages.

According to a further aspect of the invention, the focusing element is arranged at a distance of its focal length from the first deflection element or from the first beam splitter, preferably or from at least a second deflection element or from at least a second beam splitter, and the fiber array is arranged at a distance of the focal length of the focusing element from the focusing element.

Such an optical arrangement can be called a 2f-setup, which can ensure that the angular divergence of the first deflection element, preferably as a diffractive element, can be corrected, and that the individual beam sizes of the individual beams, i.e., the individual laser beams, can be focused in the Fourier plane, where the fiber array can be arranged.

According to a further aspect of the invention, the coupling device further comprises at least one magnifying device, preferably with at least one mirror section or imaging optics, which is designed and arranged to receive the deflected or split laser beams from the first deflection element or from the first beam splitter, preferably or from at least one second deflection element or from at least one second beam splitter, and to guide them to the focusing element and to increase their distance from each other in the process.

This can lead to an increase in the distance between the laser beams, which preferably allows a complete spatial separation of the individual beams or a larger mode of the individual beam, which can be advantageous for coupling. This also allows the distance between the fiber elements of the fiber array to be increased, for example by spacing the fiber elements apart and/or by using fiber elements with a correspondingly large cross-section. Thus, the laser beams can be spread out relative to each other, i.e., their distance from each other can be increased at least substantially perpendicularly to their direction of propagation. This can increase the design freedom. This can be done relatively easily using a mirror section or imaging optics.

According to a further aspect of the invention, the coupling device further comprises at least one telescope device which is designed and arranged to receive the deflected or split laser beams from the first deflection element or from the first beam splitter, preferably or from at least one second deflection element or from at least one second beam splitter, and to guide them to the focusing element, and to increase their angular expansion and reduce the beam size in the process.

The use of a telescope device can make it possible to increase the angular expansion while simultaneously reducing the beam size, which can further improve or expand the design possibilities. This can preferably allow, to the benefit of efficient and channel-separated coupling into the fiber array, for the individual beams to have a mode size, at the location of the fiber array, that matches the mode field size of the fiber and to have the correct spacing of the channels or laser beams according to the pitch of the fibers. In this case, the pitch can be defined as the distance between the respective individual fiber elements within the fiber array. Since the required foci can be very small depending on the fiber, for example approximately 3 µm to approximately 10 µm radius, a micro-lens array placed directly in front of the fiber elements can be advantageous, in order to achieve additional focusing immediately before the laser beams enter the fiber elements of the fiber array. In order to utilize this, the mode size of the individual beams or the laser beams can be smaller than the pitch and split to such an extent that the individual beams do not overlap. The telescope device can be used for this purpose, and thus significantly increase the possible number of channels.

According to a further aspect of the invention, the coupling device further comprises a plurality of micro-lenses which are designed and arranged to each receive exactly one deflected or split laser beam from the focusing element and to guide this in each case to exactly one of the fiber elements of the fiber array and to focus it further in the process.

This can improve the focusing of the laser beams, in particular in the case of small foci of the fiber elements of the fiber array, as previously described.

According to a further aspect of the invention, the focusing element is arranged at a distance of less than its focal length from the first deflection element or the first beam splitter, preferably or from a second deflection element or from a second beam splitter, the coupling device further comprising a plurality of micro-wedges which are designed and arranged to each receive exactly one deflected or split laser beam from the focusing element and to guide it in each case to exactly one of the fiber elements of the fiber array.

In this case, the beam radii to be achieved can be in the range of 3 µm to 15 µm for single-mode fibers or for LMA fibers. The spatial region to be filled, given by the pitch spacing of the array and the number of channels, combined with small splitting angles of the deflection elements, may necessitate long focal length focusing elements in a simple arrangement, which are not suitable for achieving these small beam radii at the coupling point. This link between geometry and focus size can be eliminated in this way according to the invention.

The plurality of micro-wedges can parallelize the laser beams before the laser beams reach the fiber array or its fiber elements. In this case, the focusing element can be selected so that the beam diameter of the individual beams or the laser beams in the focus matches the respective fiber element. The laser beams can overlap at the focusing element, so that the laser beams can only be separated at the position of the micro-wedges. This design can avoid using a micro-lens array as a focusing element.

According to another aspect of the invention, the focusing element is a micro-lens array, the micro-lenses of the micro-lens array together forming a curved surface which is designed to each receive the deflected or split laser beam from exactly one micro-lens of the micro-lens array, in a straight line, and guide it in a straight line to the focusing element.

This allows for a comparatively simple setup, which, however, may require very precise alignment of the fiber elements of the fiber array and the individual micro-lenses of the micro-lens array. In this case, it may be necessary for the mode diameters of the individual beams to be smaller than the pitch of the channels.

According to a further aspect of the invention, the focusing element is a micro-lens array, the coupling device further comprising a plurality of micro-wedges which are designed and arranged to each receive exactly one deflected or split laser beam from the first deflection element or from the first beam splitter, preferably or from at least one second deflection element or from at least one second beam splitter, to deflect it angularly, and to guide it parallel to each other to exactly one micro-lens of the micro-lens array.

In this case, an arrangement of micro-wedges with suitable wedge angles can be used to compensate for the angular divergence for the micro-lens array as a focusing element, so that the micro-lens array can have a simple planar geometry. The focusing into the fiber elements is then achieved by the micro-lens array and by the parallel fiber elements of the fiber array. In this case, specially designed wedge plates can reduce the complexity of the coupling and the fiber array arrangement. In any case, it can also be advantageous here that the mode diameters of the individual beams or the individual laser beams are smaller than the pitch of the channels.

According to a further aspect of the invention, the focusing element is freeform optics, the coupling device further comprising a plurality of micro-wedges which are designed and arranged to each receive exactly one deflected or split laser beam from the first deflection element or from the first beam splitter, preferably or from at least one second deflection element or from at least one second beam splitter, to deflect it angularly, and to guide it parallel to each other to the focusing element.

Thus, freeform optics can be used, which, as one element, can compensate for the angular divergence and focus into the fiber array. The freeform optics can be a specially designed surface that can combine the function of wedges and micro-lenses in a precisely manufactured phase mask. This allows both elements to be combined in a high-precision component, which can significantly reduce the complexity of the setup.

Specially designed freeform optics can allow angle correction and coupling into the fiber array arrangement. Here too, it can be advantageous for the mode diameters of the individual beams to be smaller than the pitch of the channels.

Each of the previously described uses of micro-wedges, micro-lenses or freeform optics may preferably additionally include a telescope for better angular splitting and for reducing the mode diameters of the individual beams or the individual laser beams. In this case, for efficient and channel-separated coupling of the individual laser beams into the fiber array, the individual beams at the location of the fiber array can have a mode size that matches the mode field size of the fiber elements and has the correct distance between the channels according to the pitch of the fibers. For the use of a micro-lens array, micro-wedge plates or freeform optics, it can be advantageous if the mode size of the individual beams or of the individual laser beams is smaller than the pitch and split to such an extent that the individual beams do not overlap. The telescope can be used for this purpose, and thus significantly increase the possible number of channels.

According to another aspect of the invention, the fiber elements of the fiber array each have a mode field adapter for receiving exactly one deflected or split laser beam.

The use of mode field adapters can allow the coupling of laser beams with larger focus diameters. Correspondingly, larger foci of the individual beams can be made possible.

According to a further aspect of the invention, the fiber elements of the fiber array each have a light-removing element which is designed to remove laser light of the respective deflected or split laser beam, not coupled into a fiber core of the respective fiber elements, from the fiber element, preferably from a fiber cladding of the fiber element. This also applies to another light-guiding structure, which can be used alternatively or additionally to the fiber core.

Thus, the fiber elements of the fiber array can additionally have a light-removing element as a so-called cladding light stripper, which can filter or remove laser radiation not located in the core. This can be advantageous in order to transfer and make use of light guided only in the fiber core, through the fiber elements of the fiber array, which makes it possible to maintain or achieve a high beam quality. At high power levels, a light-removing element can be particularly advantageous, since in the case of poor coupling or in the case of channels switching in a dynamic or switchable deflection element, preferably as a diffractive element, laser radiation in the fiber cladding can lead to thermal problems and the destruction of fiber components.

According to a further aspect of the invention, at least the first deflection element or the first beam splitter, the focusing element, and the fiber array are designed to receive the incoming laser beam with an optical power of at least 100 W.

This can allow the use of the coupling device according to the invention for industrial applications with correspondingly high optical power levels. For example, these could be applications of laser welding and the like.

### BRIEF DESCRIPTION OF THE DRAWINGS

A plurality of embodiments and further advantages of the invention are illustrated and explained in more detail below, purely schematically, in connection with the following figures, in which:

FIG. 1 is a side view of a coupling device according to the invention, according to a first embodiment;

FIG. 2 is a frontal plan view of a two-dimensional fiber array for use in all embodiments of a coupling device according to the invention;

FIG. 3 is a side view of a coupling device according to the invention, according to a second embodiment;

FIG. 4 is a side view of a coupling device according to the invention, according to a third exemplary embodiment;

FIG. 5 is a side view of a coupling device according to the invention, according to a fourth embodiment;

FIG. 6 is a side view of a coupling device according to the invention, according to a fifth embodiment;

FIG. 7 is a side view of a coupling device according to the invention, according to a sixth embodiment;

FIG. 8 is a side view of a coupling device according to the invention, according to a seventh embodiment;

FIG. 9 is a side view of a coupling device according to the invention, according to an eighth embodiment;

FIG. 10 is a side view of a coupling device according to the invention, according to a ninth embodiment;

FIG. 11 is a side view of a coupling device according to the invention, according to a tenth embodiment;

FIG. 12 is a side view of a coupling device according to the invention, according to an eleventh embodiment;

FIG. 13 is a side view of a coupling device according to the invention, according to a twelfth embodiment;

FIG. 14 is a side view of a coupling device according to the invention, according to a thirteenth embodiment;

FIG. 15 is a side view of one end of a fiber element according to a first variant of a coupling device according to the invention, according to one of the embodiments; and

FIG. 16 is a side view of one end of a fiber element according to a second variant of a coupling device according to the invention, according to one of the embodiments.

### DETAILED DESCRIPTION OF EXAMPLE EMBODIMENTS

The above figures are viewed in Cartesian coordinates. A longitudinal axis X is shown, which can also be denoted as depth X or as length X. A transverse axis Y, which can also be denoted as width Y, extends perpendicular to the longitudinal axis X. A vertical axis Z extends perpendicular to both the longitudinal axis X and the transverse axis Y, which can also be denoted as the height Z and which corresponds to the direction of gravity or the gravitational force. The longitudinal axis X and the transverse axis Y together form the horizontal X, Y, which can also be denoted as horizontal plane X, Y.

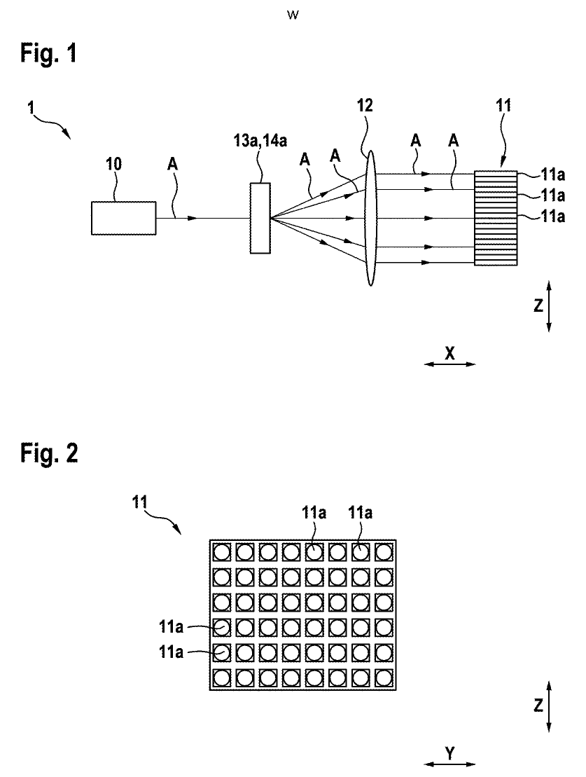

FIG. 1 is a side view of a coupling device 1 according to the invention, according to a first embodiment. FIG. 2 is a frontal plan view of a two-dimensional fiber array 11 for use in all embodiments of a coupling device 1 according to the invention.

A laser beam source 10 is present, which may or may not be a component of the coupling devices 1 according to the invention, i.e., it may be arranged outside the coupling devices 1 according to the invention. The laser source 10 can generate a laser beam A or also receive and transfer a laser beam A and, if necessary, amplify it. The laser beam A can also be referred to as laser light radiation A.

In any case, in the case of the coupling device 1 according to the invention, according to a first embodiment, the laser beam A reaches either a first deflection element 13a, which can be a first acousto-optic modulator (AOM) 13a. In this case, the incoming laser beam A is split two-dimensionally into a plurality of outgoing laser beams A, which can occur with a temporal offset or sequentially and thus alternatively to each other (not shown), which can be described as temporally dynamic, each of the outgoing laser beams A having approximately the same optical power as the incoming laser beam A. Alternatively, the first acousto-optic modulator 13a can also split the incoming laser beam A into a plurality of parallel and simultaneously emerging laser beams A, cf. FIG. 1, which can be described as temporally static. Alternatively, this can also take place by means of a first beam splitter 14a in the form of a first diffractive optical element (DOE) 14a.

In any case, the laser beams A, which emerge in a star shape in a temporally offset manner or simultaneously subsequently reach a focusing element 12, which in the case of the coupling device 1 according to the invention, according to the first embodiment, is realized as a lens 12, but can alternatively also be a micro-lens array 12, a concave mirror 12, a paraboloid 12 or freeform optics 12, as will be described further in part with reference to one of the following embodiments. In this case, the laser beams A are each focused by means of the lens 12 and aligned parallel to each other, and each directed towards a fiber element 11a of a fiber array 11, in order to enter the respective fiber element 11. The fiber elements 11a can also be referred to as optical fibers 11a.

The fiber elements 11a of the fiber array 11 guide the received laser beams A from the end (not shown) into which the laser beams A enter, to the opposite end (not shown), in order to exit there in a desired arrangement and, for example in the context of an application of laser welding, to act on a body in order to weld it. For this purpose, correspondingly high power levels of, for example, 100 W of the incoming laser beam A can be used. For this purpose, the fiber elements 11a of the fiber array 11 can preferably be arranged in a two-dimensional rectangular shape, see FIG. 2.

In this case, the first embodiment of a coupling device 1 according to the invention has only one plane of a first temporally static or temporally dynamic deflection element 13a or of a first beam splitter 14a, which can also be regarded as three separate embodiments, but due to their commonality that only one first deflection element 13a or one first beam splitter 14a is present between the laser source 10 and the focusing element 12, they can be represented by FIG. 1.

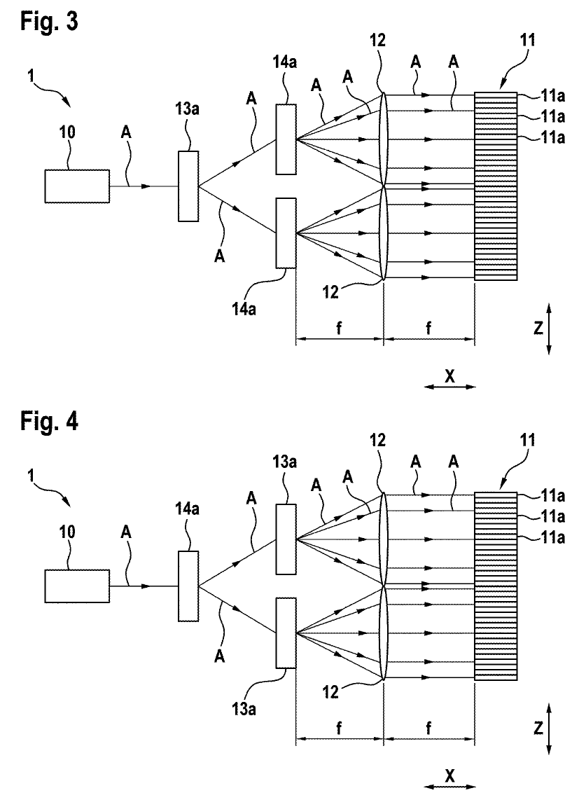

FIG. 3 is a side view of a coupling device 1 according to the invention, according to a second embodiment.

In this case, a deflection or beam splitting takes place in two planes, in that the outgoing laser beams A of the first deflection element 13a each reach a first beam splitter 14a and are split there multiple times. In this case, one focusing element 12 is present per first beam splitter 14a, as described above, in order to couple the laser beams A into a correspondingly large fiber array 11, as described above. The focusing element 12 is also arranged at a distance of its focal length f from the first deflection element 13a or from the first beam splitter 14a, and the fiber array 11 is arranged at a distance of the focal length f of the focusing element 12 from the focusing element 12, as will be described in more detail with reference to the fifth embodiment of FIG. 6.

FIG. 4 is a side view of a coupling device 1 according to the invention, according to a third embodiment.

In this case, after the laser source 10, the laser beam A first reaches a first beam splitter 14a as the first plane, and from there a plurality of first temporally static or temporally dynamic deflection elements 13a as the second plane. The focusing element 12 then follows, as described above.

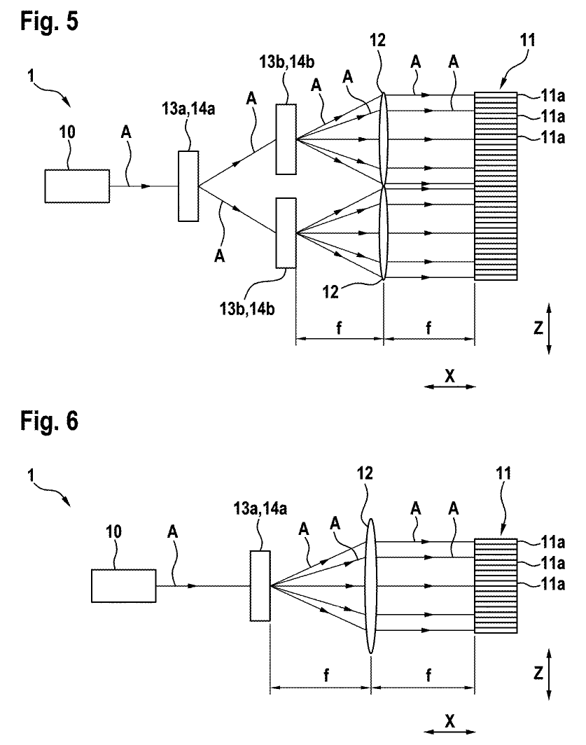

FIG. 5 is a side view of a coupling device 1 according to the invention, according to a fourth embodiment.

The possibility is presented to either combine a first temporally static or temporally dynamic deflection element 13a in the first plane with a plurality of second temporally static or temporally dynamic deflection elements 13b in the second plane, or to combine a first beam splitter 14a in the first plane with a plurality of second beam splitters 14b in the second plane.

FIG. 6 is a side view of a coupling device 1 according to the invention, according to a fifth embodiment.

The arrangement of the fifth embodiment of FIG. 6 corresponds to the first embodiment of FIG. 1, with the specification that the focusing element 12 is arranged at a distance of its focal length f from the first deflection element 13a or from the first beam splitter 14a. Likewise, the fiber array 11 is arranged at a distance of the focal length f of the focusing element 12 from the focusing element 12. This allows the angular divergence of the first deflection element 13a to be corrected and the individual beam sizes of the individual laser beams A to be focused in the Fourier plane where the fiber array 11 is arranged.

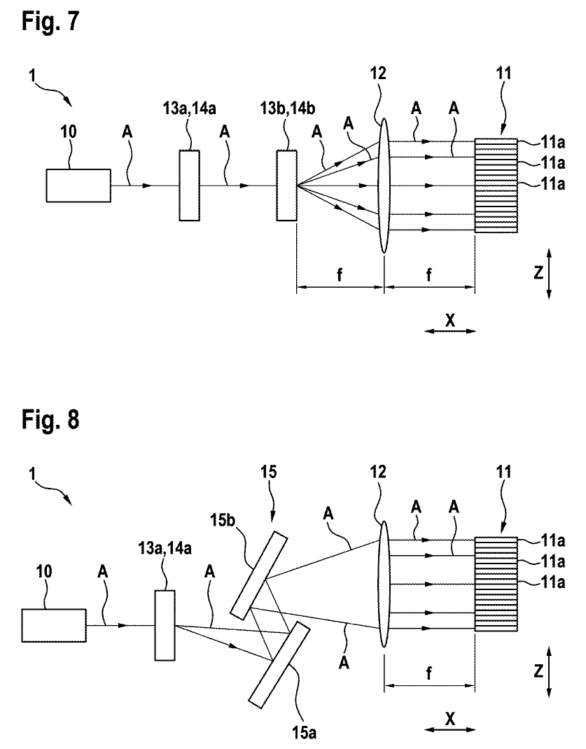

FIG. 7 is a side view of a coupling device 1 according to the invention, according to a sixth embodiment.

In this case, either the first deflection element 13a is arranged in the first plane and a second deflection element 13b in the second plane, or a first beam splitter 14a is arranged in the first plane and a second beam splitter 14b in the second plane. In this case, the deflection elements 13a, 13b or the beam splitters 14a, 14b are each designed to be one-dimensionally deflecting or splitting, so that in the first plane deflection or splitting occurs in each case along the transverse axis Y, and subsequently in the second plane deflection or splitting occurs in each case along the vertical axis Z. This can simplify the implementation of the deflection elements 13a, 13b or the beam splitters 14a, 14b, since these only need to be designed to act in one dimension.

In addition, the arrangement of the focusing element 12 at a distance of its focal length f from the second deflection element 13b or from the second beam splitter 14b is used in combination with the arrangement of the fiber array 11 at a distance of the focal length f of the focusing element 12 from the focusing element 12, in order to achieve the corresponding focusing described above.

FIG. 8 is a side view of a coupling device 1 according to the invention, according to a seventh embodiment.

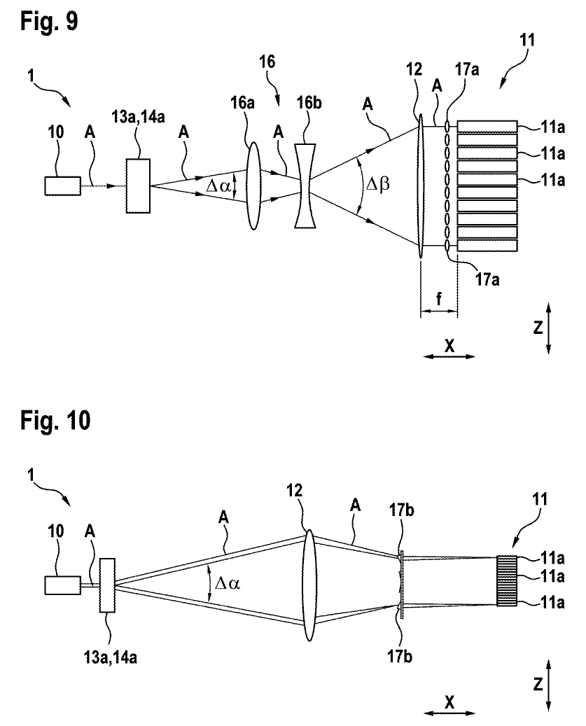

In this case, a magnifying device 15 in the form of a mirror section 15 with a first deflecting mirror 15a and with a second deflecting mirror 15b or imaging optics 15 is used to receive the deflected or split laser beams A from the first deflection element 13a or from the first beam splitter 14a and to guide them to the focusing element 12 and increase their distance from each other in the process. The mirror section 15 can serve to achieve complete separation of the individual modes in a comparatively compact installation space, so that said modes can be focused separately, for example with additional micro-lenses 17a, see FIG. 9. This allows the distance between the fiber elements 11a of the fiber array 11 to be increased in order to be coupled into a corresponding arrangement of fiber elements 11a of the fiber array 11.

FIG. 9 is a side view of a coupling device 1 according to the invention, according to an eighth embodiment.

In this case, a telescope device 16 with a lens 16a and an eyepiece 16b is used to receive the deflected or split laser beams A from the first deflection element 13a or from the first beam splitter 14a and guide them to the focusing element 12, and to increase their angular expansion and reduce the beam size in the process. In this case, the laser beams A enter the lens 16a of the telescope device 16 at a first angle Δ α and exit the eyepiece 16b again at a second, larger angle Δ β, in order to then enter the focusing element 12 and be focused there. Between the focusing element 12 and the fiber array 11, a micro-lens 17a is provided for each laser beam A in order to achieve further focusing towards the respective fiber element 11a. This makes it possible to achieve an increase in the angular expansion, while simultaneously reducing the beam size of the laser beams A.

FIG. 10 is a side view of a coupling device 1 according to the invention according, to a ninth embodiment.

In this case, the focusing element 12 is arranged at a distance of less than its focal length f from the first deflection element 13a or from the first beam splitter 14a. Furthermore, a plurality of micro-wedges 17b is provided, which micro-wedges are designed and arranged to each receive exactly one deflected or split laser beam A from the focusing element 12 and to guide it to exactly one of the fiber elements 11a of the fiber array 11 in each case. The micro-wedges 17b are used with suitable wedge angles, in order to compensate for the angular divergence of the focusing element 12.

This arrangement allows the use of focusing elements 12 with a comparatively short focal length, which can expand the design possibilities for the necessary focusing on the fiber elements 11a. The beam radii to be achieved can be in the range, here, from 3 µm to 15 µm, for single-mode or LMA fibers. The spatial region to be filled, given by the pitch spacing of the fiber array 11 and the number of channels, combined with small splitting angles of the deflection elements 13a, necessitates long focal length focusing elements in a simple arrangement, which are not suitable for achieving these small beam radii at the coupling point. This link between geometry and focus size is eliminated by the embodiment.

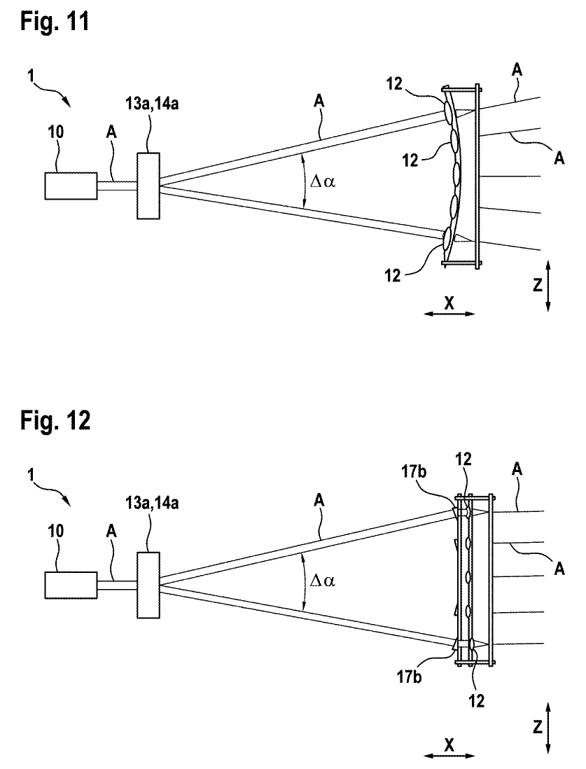

FIG. 11 is a side view of a coupling device 1 according to the invention, according to a tenth embodiment.

In this case, the focusing element 12 is a micro-lens array 12, the micro-lenses of the micro-lens array 12 together forming a curved surface which is designed to each receive the deflected or split laser beams A from exactly one micro-lens of the micro-lens array 12 in a straight line, and guide them in a straight line to the focusing element 12. This results in a star-shaped propagation of the laser beams A, so that the fiber elements 11a (not shown) are arranged and aligned accordingly, in order to couple the laser beams A in a straight line.

FIG. 12 is a side view of a coupling device 1 according to the invention, according to an eleventh embodiment.

In this case too, the focusing element 12 is a micro-lens array 12. Furthermore, a plurality of micro-wedges 17b is provided, which micro-wedges are designed and arranged to each receive exactly one deflected or split laser beam A from the first deflection element 13a or from the first beam splitter 14a, deflect it angularly, and guide it parallel to each other to exactly one micro-lens of the micro-lens array 12 in each case. By means of the arrangement of micro-17b wedges with suitable wedge angles, the angular divergence of the micro-lens array 12, as the focusing element 12, can be compensated. The focusing into the fiber elements 11a is then carried out by the micro-lens array 12, arranged in a simple geometry, and by the parallel fiber elements 11a of the fiber array 11.

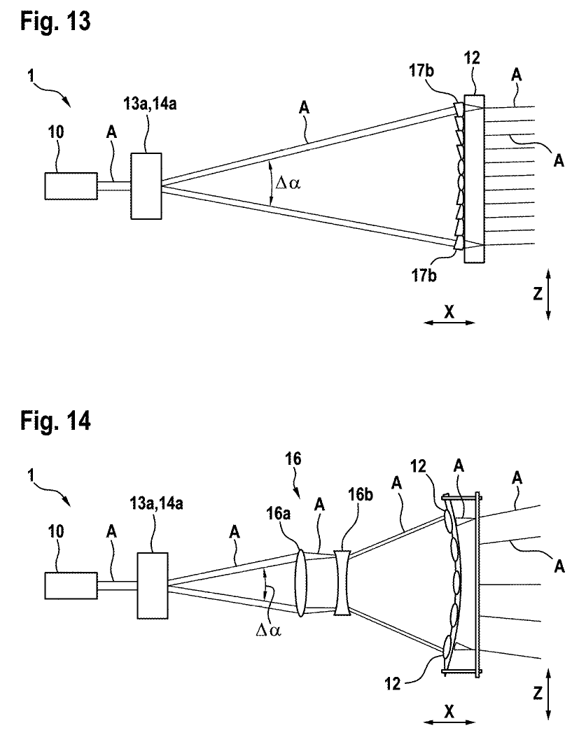

FIG. 13 is a side view of a coupling device 1 according to the invention, according to a twelfth embodiment.

In this case, the focusing element 12 is freeform optics 12 which is designed to combine the function of wedges and micro-lenses in a precisely manufactured phase mask. As a result, both elements are combined in a high-precision component, which significantly reduces the complexity of the setup. Furthermore, a plurality of micro-wedges 17b is provided, which micro-wedges are designed and arranged to each receive exactly one deflected or split laser beam A from the first deflection element 13a or from the first beam splitter 14a, to deflect it angularly, and to guide it parallel to each other to the focusing element 12. Thus, freeform optics 12 can be used, which, as one element, can compensate for the angular divergence and focus into the fiber array 11.

FIG. 14 is a side view of a coupling device 1 according to the invention, according to a thirteenth embodiment.

In this case, the focusing element 12 of FIG. 11 or of the tenth embodiment is combined as a micro-lens array 12, whose micro-lenses together form a curved surface, and the telescope device 16 with a lens 16a and with an eyepiece 16b of FIG. 9 or of the eighth embodiment.

This combination is also conceivable, in the same way, with the focusing element 12 according to the eleventh embodiment of FIG. 12 and with the twelfth embodiment of FIG. 13.

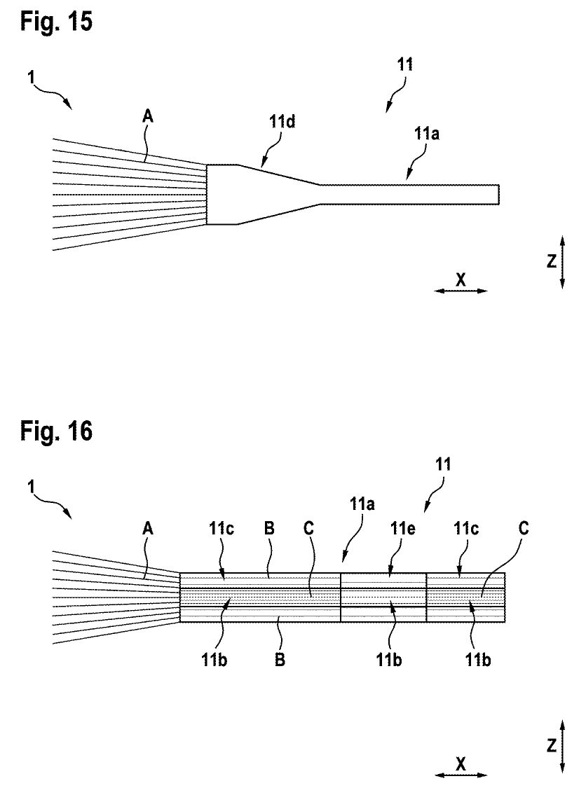

FIG. 15 is a side view of one end of a fiber element 11a according to a first variant of a coupling device 1 according to the invention, according to one of the embodiments.

The fiber elements 11a of the fiber array 11 each have a mode field adapter 11d for receiving exactly one deflected or split laser beam A. This can allow for coupling of laser beams A with larger focus diameters. Correspondingly, larger foci of the laser beams A can be made possible.

Regarding the representation of the laser beam A in FIG. 15 and 16, it should be noted that the individual solid lines in FIG. 15 and 16, which are marked with the reference sign A, are partial beams of a single laser beam A, which are coupled together into the one fiber element 11a, shown in each case, of the fiber array 11.

FIG. 16 is a side view of one end of a fiber element 11a according to a second variant of a coupling device 1 according to the invention, according to one of the embodiments.

In this case, the fiber elements 11a of the fiber array 11 each have a light-removing element 11e, which is designed to remove laser light not coupled into a fiber core 11b of the respective fiber element 11a, as cladding light radiation B of the respective deflected or split laser beam A, from a fiber cladding 11c of the fiber element 11a. Accordingly, only that part of the respective laser beam A which is located as core light radiation C in the fiber core 11b propagates further along the fiber element 11a.

Thus, laser radiation A not located in the fiber core 11b can be filtered or removed from the respective fiber element 11a of the fiber array 11 by means of the light-removing element 11e, as a result of which a high beam quality can be maintained or achieved.

For high power outputs in the range of 100 W or more, this is particularly advantageous in order to avoid damage to the fiber elements 11a. In particular, the light-removing elements 11e of the fiber elements 11a of the fiber array 11 are also suitable for this high power range.

### LIST OF REFERENCE SIGNS (PART OF THE DESCRIPTION)

Δ α first angle

Δ β second angle

A laser beams; laser light radiation

B cladding light radiation

C core light radiation

f focal length

X longitudinal axis; depth; length

Y transverse axis; width

Z vertical axis; height

X, Y horizontal, horizontal plane

1 coupling device

10 laser beam source

11 fiber array

11a fiber elements or optical fibers of the fiber array 11

11b fiber cores of the fiber array 11

11c fiber claddings of the fiber array 11

11d mode field adapter of the fiber array 11

11e light-removing element; cladding light stripper

12 focusing element; lens; micro-lens array; concave mirror; paraboloid; freeform optics

13a first deflection element; first acousto-optic modulator (AOM)

13b second deflection elements; second acousto-optic modulators (AOM)

14a first beam splitter; first diffractive optical element (DOE)

14b second beam splitter; second diffractive optical elements (DOE)

15 magnifying device; mirror section; imaging optics

15a first deflecting mirror of the magnifying device 15 or mirror section 15

15b second deflecting mirror of the magnifying device 15 or mirror section 15

16 telescope device

16a lens or concave mirror of the telescope device 16

16b eyepiece of the telescope device 16

17a micro-lenses

17b micro-wedges

What is claimed is:

1. A coupling device for coupling at least one laser beam into at least one fiber array, comprising:
at least one first deflection element or at least one first beam splitter which is designed and arranged to receive and deflect or split the laser beam multiple times,
at least one focusing element which is designed and arranged to receive and focus the deflected or split laser beams, and
at least the fiber array which has a plurality of fiber elements arranged at least one-dimensionally, preferably two-dimensionally, relative to each other.

2. The coupling device according to claim 1,
comprising at least the first deflection element, which is designed and arranged to receive the laser beam and deflect it multiple times, and
furthermore comprising at least one first beam splitter which is designed and arranged to receive one of the deflected laser beams and to split it to the focusing element,
preferably furthermore comprising at least two first beam splitters which are designed and arranged to each receive one of the deflected laser beams and split it to the focusing element, or
preferably furthermore comprising at least one second deflection element which is designed and arranged to receive the other of the deflected laser beams and to deflect them multiple times to the focusing element.

3. The coupling device according to claim 1,
comprising at least the first beam splitter which is designed and arranged to receive and split the laser beam, and
furthermore comprising at least one first deflection element which is designed and arranged to receive one of the split laser beams and to deflect it multiple times to the focusing element,
preferably furthermore comprising at least two first deflection elements which are designed and arranged to each receive one of the split laser beams and to deflect them multiple times to the focusing element , or
preferably furthermore comprising at least one second beam splitter which is designed and arranged to receive the other of the split laser beams and to split it to the focusing element.

4. The coupling device according to claim 1,
comprising the first deflection element, which is designed and arranged to receive the laser beam and deflect it multiple times, and
furthermore comprising at least two second deflection elements which are designed and arranged to each receive one of the deflected laser beams from the first deflection element and to deflect it multiple times to the focusing element.

5. The coupling device according to claim 1,
comprising the first beam splitter, which is designed and arranged to receive and split the laser beam, and
furthermore comprising two second beam splitters which are designed and arranged to each receive one of the split laser beams from the first beam splitter and split it to the focusing element.

6. The coupling device according to claim 1,
wherein the first deflection element is a first acousto-optic modulator, preferably and a second deflection element is a second acousto-optic modulator, and/or
wherein the first deflection element, preferably and a second deflection element, is configured to deflect the laser beam one-dimensionally or two-dimensionally, and/or
wherein the first beam splitter is a first diffractive optical element, preferably and a second beam splitter is a second diffractive optical element, and/or
wherein the first beam splitter, preferably and a second beam splitter, is designed to split the laser beam one-dimensionally or two-dimensionally, and/or
wherein the focusing element is a lens, a micro-lens array, a concave mirror, a paraboloid or freeform optics.

7. The coupling device according to claim 1,
wherein the focusing element is arranged at a distance of its focal length (f) from the first deflection element or from the first beam splitter, preferably or from at least a second deflection element or from at least a second beam splitter, and
wherein the fiber array is arranged at a distance of the focal length (f) of the focusing element from the focusing element.

8. The coupling device according to claim 1,
furthermore comprising at least one magnifying device, preferably comprising at least one mirror section or imaging optics, which is designed and arranged to receive the deflected or split laser beams from the first deflection element or from the first beam splitter, preferably or from at least one second deflection element or from at least one second beam splitter, and to guide them to the focusing element and increase their distance from each other in the process.

9. The coupling device according to claim 1,
furthermore comprising at least one telescope device which is designed and arranged to receive the deflected or split laser beams from the first deflection element or from the first beam splitter, preferably or from at least one second deflection element or from at least one second beam splitter, and to guide them to the focusing element and increase their angular expansion and reduce the beam size in the process.

10. The coupling device according to claim 1,
furthermore comprising a plurality of micro-lenses which are designed and arranged to each receive exactly one deflected or split laser beam from the focusing element and to guide this in each case to exactly one of the fiber elements of the fiber array and to focus it further in the process.

11. The coupling device according to claim 1,
wherein the focusing element is arranged at a distance of less than its focal length (f) from the first deflection element or from the first beam splitter, preferably or from a second deflection element or from a second beam splitter,
furthermore comprising a plurality of micro-wedges which are designed and arranged to each receive exactly one deflected or split laser beam from the focusing element and to guide this in each case to exactly one of the fiber elements of the fiber array.

12. The coupling device according to claim 1,
wherein the focusing element is a micro-lens array,
wherein the micro-lenses of the micro-lens array together form a curved surface which is designed to each receive the deflected or split laser beam from exactly one micro-lens of the micro-lens array in a straight line and to guide it in a straight line to the focusing element.

13. The coupling device according to claim 1,
wherein the focusing element is a micro-lens array,
furthermore comprising a plurality of micro-wedges which are designed and arranged to each receive exactly one deflected or split laser beam from the first deflection element or from the first beam splitter , preferably or from at least one second deflection element or from at least one second beam splitter, to deflect it angularly, and to in each case guide it parallel to each other to exactly one micro-lens of the micro-lens array.

14. The coupling device according to claim 1,
wherein the focusing element is freeform optics,
furthermore comprising a plurality of micro-wedges which are designed and arranged to each receive exactly one deflected or split laser beam from the first deflection element or from the first beam splitter, preferably or from at least one second deflection element or from at least one second beam splitter, to deflect it angularly, and to guide it parallel to each other to the focusing element.

15. The coupling device according to claim 1,
wherein the fiber elements of the fiber array each have a mode field adapter for receiving exactly one deflected or split laser beam, and/or
wherein the fiber elements of the fiber array each have a light-removing element which is designed to remove laser light of the respective deflected or split laser beam, not coupled into a fiber core of the respective fiber element, from the fiber element, preferably from a fiber cladding of the fiber element, and/or
wherein at least the first deflection element or the first beam splitter, the focusing element and the fiber array are designed to receive the incoming laser beam with an optical power of at least 100 W.
